(19) United States
(12) Patent Application Publication
(10) Pub. No.: US 2011/0241650 A1
(43) Pub. Date: Oct. 6, 2011

(54) ELECTROCHEMICAL SENSOR FOR DISINFECTANTS

(76) Inventor: Ying Zhang, Irvine, CA (US)

(21) Appl. No.: 13/164,723

(22) Filed: Jun. 20, 2011

(51) Int. Cl. G01R 19/00

(52) U.S. Cl. 324/76.11

(57) ABSTRACT

An electrochemical sensor to measure disinfectants is provided. In accordance with one aspect of the invention, the sensor has a silver working electrode disposed in an electrolyte proximate a porous membrane. There is a reference electrode made of silver in contact with the electrolyte. The chemical composition of electrolyte contains one or more anions that make the potential at the reference electrode higher than 0.35 V versus standard hydrogen electrode. The anions form silver salt with solubility higher than the solubility of silver chloride. The voltage at the working electrode versus the reference electrode is maintained negative to keep the background current small enough while maintains the feasibility to reduce disinfectants. Solid phase silver salt of the anions is added within the sensor body, which will prevent poisoning the reference electrode by halide anions diffused into the electrolyte.

### BACKGROUND OF THE INVENTION

The present invention relates to a sensor that uses an electrode response to measure the concentration of disinfectants in various solutions. Free chlorine, chlorine dioxide, chloroamine, and ozone shall be mentioned as examples of disinfectants here.

Disinfectants in solutions are often measured by electrochemical sensors. The electrochemical sensor is characterized by: a sensor body, a working electrode, a counter electrode, a reference electrode, and an electrolyte solution. The electrolyte sets up electric contact among these electrodes. The working electrode, the counter electrode, the reference electrode, and the electrolyte are disposed within the sensor body. The measurement is based on the reduction of disinfectants at the working electrode, whose current is related to the concentration of the disinfectants in sample solutions. The reference electrode and the counter electrode are often combined into one electrode. Rosemount Analytical Incorporated, an Emerson Process Management Company, provides a free chlorine sensor for the continuous determination of free chlorine, under the trade designation model 499ACL-01. The sensor can measure free chlorine in samples and operates as an amperometric sensor.

The sensor is actuated by an electronic device. The electronic device maintains a voltage bias between the working electrode and the reference electrode and measures the current flowing through the working electrode.

In general, prior art electrochemical sensors for disinfectants have the reference electrode being silver-silver halide in an electrolyte containing different concentrations of halide (e.g., >0.035 mole per liter of chloride, bromide, or iodide). The reference potential is lower than 0.35 V versus standard hydrogen electrode. The voltage at the working electrode is maintained positive or neutral versus the reference electrode. The working electrode is metals that are more stable and more expensive than silver. Gold and platinum shall be mentioned as examples here. The use of gold or platinum working electrode counts a big percentage of material expense for the sensor.

It would be extremely useful if electrochemical sensors for disinfectants could be done with silver working electrode. The expense of silver is about ten times less than the expense of gold or platinum. This would advance the art of electrochemical sensors for disinfectants and lower overall costs for providing disinfectant measurement systems. If silver is used to replace gold or platinum as the working electrode in the prior art electrochemical sensors for disinfectants, the working electrode will have unacceptable background current, corrosion and passivation because of the oxidation of silver in the working electrode.

One aspect of the electrochemical sensor for disinfectants is designed to minimize the background current while makes the reduction of disinfectant feasible. If the voltage at the working electrode is maintained too low, some chemicals in the electrolyte other than disinfectant may become active to be reduced, which leads to a too big background current. Oxygen shall be mentioned as example here. If the voltage at the working electrode is maintained too high, one detrimental effect is the reduction of disinfectants becomes not feasible. Another detrimental effect is that some chemicals in the electrolyte and the metal of the working electrode may becomes active to be oxidized, which leads to a big background current with an opposite direction to the current for disinfectants. With voltage at the working electrode maintained positive versus silver-silver halide reference electrode, the metal in the working electrode will be oxidized if silver is used as the working electrode. This will produce unacceptable high background current, corrode the working electrode and passivate the reduction of disinfectant. To avoid the oxidation of silver working electrode, it is necessary to maintain the voltage at the working electrode negative versus the silver based reference electrode.

The reduction of disinfectants at the working electrode is determined by the potential of the working electrode versus standard hydrogen electrode rather than the voltage at the working electrode versus the reference electrode. The potential of the working electrode is the combination of the voltage bias at working electrode versus the reference electrode and the potential of the reference electrode. For the feasibility to reduce disinfectant, the negative shift in the potential maintained at the working electrode versus the reference electrode can be compensated by the same amplitude positive shift in the potential of the reference electrode (Table 1). However, the background current is also influenced by the chemicals involved in the reference electrode equilibrium.

TABLE 1
voltage at working electrode versus different reference electrode

| Versus Ag/AgCl, 3.5M | versus Ag/Ag2SO4, 1M | Sensitivity |
|---|---|---|
| KCl | na2SO4 | (nA/ppm) |
| 0.25 | −0.255 | 34 |
| 0.2 | −0.305 | 43 |
| 0.15 | −0.355 | 45 |
| 0.1 | −0.405 | 49 |
| 0.05 | −0.455 | 50 |
| 0 | −0.505 | 53 |

One strategy for the present invention is to design the reference electrode that has its reference potential higher than 0.35 V versus standard hydrogen electrode. The potential of the silver reference electrode is determined by the equilibrium between the silver and silver ion in the electrolyte, which is then in equilibrium with anions in the electrolyte and silver salt precipitate within the sensor body. The approach for the present invention is characterized with a silver reference electrode in equilibrium with silver salts that have solubility higher than silver chloride, which allow the concentration of silver ions in the electrolyte higher than 0.0008 milligram per liter. The reference potential is higher than 0.35 V versus standard hydrogen electrode. Silver in equilibrium with silver sulfate precipitate coupled with sulfate solution, silver phosphate precipitate coupled with phosphate solution, silver hydroxide in pH<9, silver citrate precipitate coupled with citrate solution, silver carbonate precipitate coupled with pH<10 carbonate solution shall be mentioned as examples here. With such a reference electrode, the voltage at working electrode is maintained negative while the feasibility to reduce disinfectants and the background current are both acceptable.

All referenced patents, applications and literatures are incorporated herein by reference in their entirety. Furthermore, where a definition or use of a term in a reference, which is incorporated by reference herein, is inconsistent or contrary to the definition of that term provided herein, the definition of that term provided herein applies and the definition of that term in the reference does not apply. The invention may seek to satisfy one or more of the above-mentioned desires. Although the present invention may obviate one or more of the above-mentioned desires, it should be understood that some aspects of the invention might not necessarily obviate them.

### SUMMARY OF THE INVENTION

An electrochemical sensor to measure disinfectants is provided. In accordance with one aspect of the invention, the sensor has a working electrode disposed in an electrolyte proximate a porous membrane. The membrane allows disinfectant diffuse through toward working electrode where it is reduced and generates a current. The current is related to the concentration of disinfectants. The reference potential of the reference electrode is higher than 0.35 V versus standard hydrogen electrode by using an electrolyte contains anions that allow silver ions in the electrolyte higher than 0.0008 milligram per liter.

The potential at the working electrode is maintained negative versus the reference electrode. The background current for the silver working electrode will be low enough to be acceptable and the silver working electrode will not be troubled by corrosion and passivation. Another aspect is that solid phase silver salts whose solubility is higher than the solubility of silver chloride is added within the sensor body to avoid poisoning the reference electrode by halide anions. The solid of that silver salt within the sensor body will react with anions that form silver salt precipitate with lower solubility.

Various objects, features, aspects and advantages of the present invention will become more apparent from the following detailed description of preferred embodiments of the invention, along with the accompanying drawings in which like numerals represent like components.

### DETAILED DESCRIPTION OF THE PREFERRED EMBODIMENTS

The invention and its various embodiments can now be better understood by turning to the following detailed description of the preferred embodiments, which are presented as illustrated examples of the invention defined in the claims. It is expressly understood that the invention as defined by the claims may be broader than the illustrated embodiments described below.

Many alterations and modifications may be made by those having ordinary skill in the art without departing from the spirit and scope of the invention. Therefore, it must be understood that the illustrated embodiment has been set forth only for the purposes of example and that it should not be taken as limiting the invention as defined by the following claims. For example, notwithstanding the fact that the elements of a claim are set forth below in a certain combination, it must be expressly understood that the invention includes other combinations of fewer, more or different elements, which are disclosed herein even when not initially claimed in such combinations.

The words used in this specification to describe the invention and its various embodiments are to be understood not only in the sense of their commonly defined meanings, but to include by special definition in this specification structure, material or acts beyond the scope of the commonly defined meanings. Thus if an element can be understood in the context of this specification as including more than one meaning, then its use in a claim must be understood as being generic to all possible meanings supported by the specification and by the word itself.

The definitions of the words or elements of the following claims therefore include not only the combination of elements which are literally set forth, but all equivalent structure, material or acts for performing substantially the same function in substantially the same way to obtain substantially the same result. In this sense it is therefore contemplated that an equivalent substitution of two or more elements may be made for any one of the elements in the claims below or that a single element may be substituted for two or more elements in a claim. Although elements may be described above as acting in certain combinations and even initially claimed as such, it is to be expressly understood that one or more elements from a claimed combination can in some cases be excised from the combination and that the claimed combination may be directed to a subcombination or variation of a subcombination.

Embodiments of the present invention provide an electrochemical sensor with a silver working electrode to measure the concentration of disinfectants. This arrangement provides a useful electrochemical sensor for disinfectants that can operate without expensive gold or platinum working electrode. Silver working electrode is disposed proximate porous membrane. In one preferred embodiment, the working electrode is a silver disk. Other forms of electrodes, such as a silver mesh or silver ring, can be used too.

The present invention includes a silver reference electrode being disposed in electrolyte solution. The anions in the electrolyte solution allow silver ions dissolved in the electrolyte higher than 0.0008 milligram per liter. Satisfactory performance has been found for anions that form silver salt with solubility higher than silver chloride. Concentrated sulfate solution, phosphate solution in pH<9, carbonate solution in pH<10, hydroxide in pH<10, citrate solution shall be mentioned as examples here. The potential of the silver reference electrode is higher than 0.35 V versus standard hydrogen electrode.

To avoid poisoning the reference electrode, solid phase silver salts whose solubility is higher than the solubility of silver chloride is added. Such silver salt solid is used as scavenge to react with chloride and other anions that can form silver salt whose solubility is similar to or less than the solubility of silver chloride. For example, at least one of solid phase silver sulfate, silver phosphate, silver hydroxide, silver oxide, silver carbonate, or silver citrate is added into the sensor body. In this way, the presence of chloride, bromide or iodide will not poison the silver reference electrode.

One important design consideration for a sensor of this type is the potential at working electrode. The potential of the working electrode is the combination of the voltage bias at working electrode versus the reference electrode and the potential of the reference electrode. The potential at working electrode should minimize background current while guaranteeing the feasibility to reduce disinfectants. The reduction of disinfectants becomes more feasible as the potential at working potential decreased. When the potential at the working electrode is too low, some chemicals in the electrolyte solution may become active to be reduced. Oxygen shall be mentioned as example here. When the potential at the working electrode is high, a contribution to background current is that some chemicals in the electrolyte become active to be oxidized. Another contribution to background current is caused by the oxidation of the metal of the working electrode. With silver reference electrode, any positive voltage bias at working electrode versus the reference electrode will likely lead to the oxidation of silver in the working electrode. To avoid the oxidation of silver in the working electrode, the preferable embodiment is that the potential at the silver working electrode is maintained negative versus the silver reference electrode. Satisfactory performance has been found when the potential at the working electrode is maintained negative versus the reference electrode and the reference electrode is silver equilibrium with silver sulfate and 2 M sodium sulfate (Table 2).

TABLE 2
Amperometric Sensor for Free Chlorine with Silver Working Electrode
and Silver Reference Electrode in 2M Sodium Sulfate

| Voltage biased at working elec- | Background | Sensitivity for free |
|---|---|---|
| trode vs reference electrode | signal | chlorine |
| −0.25 | 12 | 55 |
| −0.225 | 2 | 53 |
| −0.2 | −10 | 50 |

Thus, specific embodiments and applications of electrochemical sensor for disinfectant have been disclosed. It should be apparent, however, to those skilled in the art that many more modifications besides those already described are possible without departing from the inventive concepts herein. The inventive subject matter, therefore, is not to be restricted except in the spirit of the appended claims. Moreover, in interpreting both the specification and the claims, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced. Insubstantial changes from the claimed subject matter as viewed by a person with ordinary skill in the art, now known or later devised, are expressly contemplated as being equivalent within the scope of the claims. Therefore, obvious substitutions now or later known to one with ordinary skill in the art are defined to be within the scope of the defined elements. The claims are thus to be understood to include what is specifically illustrated and described above, what is conceptually equivalent, what can be obviously substituted and also what essentially incorporates the essential idea of the invention. In addition, where the specification and claims refer to at least one of something selected from the group consisting of A, B, C . . . and N, the text should be interpreted as requiring only one element from the group, not A plus N, or B plus N, etc.

What is claimed is:

1. A system for monitoring concentration of disinfectants, the system comprising: an electrochemical sensor for measuring disinfectants, the sensor comprising: a sensor body; an electrolyte disposed within the sensor body; a membrane coupled to the sensor body and adapted to pass disinfectants into the sensor body; a working electrode disposed proximate the membrane, the working electrode being made of silver; a reference electrode disposed in the electrolyte, the reference electrode being silver in equilibrium with the electrolyte; and an electronic device coupled to the sensor, the electronic device adapted to maintain a potential difference between the working electrode and the reference electrode and to measure the current flowing through the working electrode.

2. The sensor of claim 1, wherein the sensor further comprising a counter electrode. The counter electrode adapted to form a current loop together with the working electrode.

3. The sensor of claim 1, wherein the potential of the reference electrode is higher than 0.35 V versus standard hydrogen electrode and the voltage at working electrode the reference electrode is maintained negative versus.

4. The sensor of claim 3, wherein silver in the reference electrode is in equilibrium with at least one anion in the electrolyte and its silver salt precipitate within the sensor body. The anion allows silver ion dissolved in electrolyte higher than 0.0008 milligram per liter.

5. The sensor of claim 4, wherein there is silver phosphate precipitate within the sensor body.

6. The sensor of claim 4, wherein there is silver hydroxide precipitate within the sensor body.

7. The sensor of claim 4, wherein there is silver sulfate precipitate within the sensor body.

8. The sensor of claim 4, wherein there is silver citrate precipitate within the sensor body.

9. The sensor of claim 4, wherein there is solid phase silver salt added within the sensor body. The silver salt has solubility higher than the solubility of silver chloride.

10. The sensor of claim 1, wherein the disinfectant being free chlorine.

11. The sensor of claim 1, wherein the disinfectant being chlorine dioxide.

12. The sensor of claim 1, wherein the disinfectant being chlorine bonded to nitrogen atoms.

13. The sensor of claim 1, wherein the disinfectant being ozone.
